(19) United States
(12) Patent Application Publication
(10) Pub. No.: US 2008/0185043 A1
(43) Pub. Date: Aug. 7, 2008

(54) Microfluidic Device

(75) Inventors: Menno Willem Jose Prins, Rosmalen (NL); Johannus Wilhelmus Weekamp, Beek en Donk (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/718,805

(22) PCT Filed: Nov. 15, 2005
(86) PCT No.: PCT/IB05/53760

§ 371 Date: May 8, 2007

(30) Foreign Application Priority Data
Nov. 16, 2004 (EP) 04105801.7

(51) Int. Cl. F17D 1/08; B81C 1/00; B81B 7/00

(52) U.S. Cl. 137/2; 137/802; 29/890.09

(57) ABSTRACT

A microfluidic device for guiding the flow of a fluid sample is disclosed. The microfluidic device comprises a base plate (1) that extends in two lateral directions and has at least one through-going recess (1.1) in the vertical direction; a flow-through unit (2) that has at least a first and a second flow-through site (3.1, 3.2); and a plate structure (4). The flow-through unit (2) is arranged relatively to the recess (1.1) of the base plate (1) so that a vertical fluid flow from one side of this arrangement to the opposite side through each of the first and the second flow-through sites (3.1, 3.2) is enabled. Further, the plate structure (4) and the flow-through unit (2) are arranged relatively to each other so that a linking channel cavity (41) is formed for enabling a lateral fluid flow from the first to the second flow-through site (3.1, 3.2).

The invention relates to a microfluidic device for guiding the flow of a fluid sample, a method of guiding the flow of a fluid sample, and a method of manufacturing a microfluidic device.

From US patent application US 2004/0051154 A1 a microfluidic device is known that has upper and lower channels formed in respective halves of a substrate, which halves are sandwiched around one or more porous membranes upon assembly. Upper and lower channels have at least one cross-channel area, wherein the membrane is disposed between the two channels. The porous membranes may have a sensing characteristic and detection equipment may be provided to measure the changes in the sensing characteristic.

The microfluidic device as known from US 2004/0051154 A1 needs two equally sized halves to form channels. To achieve different upper and lower channels, the channels must have different courses as the lower or upper halve forms one of the walls of the upper or lower channels. At positions where channels cross each other there is automatically generated a clearance so that a fluid flow between the upper and the lower channel is enabled.

It is therefore an object of the present invention to provide a microfluidic device that is improved in comparison with the known microfluidic devices.

The object of the invention is solved by a microfluidic device for guiding the flow of a fluid sample comprising a base plate extending in two lateral directions and having at least one through-going recess in the vertical direction; a flow-through unit having at least a first and a second flow-through site; and a plate structure, wherein the flow-through unit is arranged relatively to the recess of the base plate so that a vertical fluid flow from one side of this arrangement to the opposite side through each of the first and the second flow-through sites is enabled; and the plate structure and the flow-through unit are arranged relatively to each other so that a linking channel cavity is formed for enabling a lateral fluid flow from the first to the second flow-through site.

Hence, a multilayer microfluidic device can be provided in which the plate structure can be about as small as, or even smaller than, the flow-through unit. The linking channel cavity that connects the first and second flow-through site defines a lateral channel at a first vertical position. A second lateral channel at a different vertical position can be created as described further below.

The linking channel cavity could be formed in different ways, e.g. by a depression in the flow-through unit or in the plate structure, which depression is open on one side, and, depending on which contains the depression, by an exterior side of the flow-through unit or plate structure, so that a closed channel results. This can be easily accomplished by positioning the exterior side so that it covers the depression. Alternatively, the linking channel cavity can be formed by a depression in each of the flow-through unit and the base plate and by arranging both so that the depressions cooperate to form the closed linking channel cavity. Further, the linking channel cavity can be formed by a part of the recess in the base plate and by cooperating exterior sides of the flow-through unit and the plate structure, where the flow-through unit and/or the plate structure could alternatively have depressions that cooperate with the part of the recess of the base plate to form the closed linking channel cavity.

Instead of having only one flow-through unit, the microfluidic device could be equipped with a plurality of flow-through units at different lateral positions on the base plate.

In one embodiment of the invention, another lateral channel layer at a different vertical position than the linking channel cavity is formed by arranging a channel structure on the base plate side opposite the plate structure. The channel structure can be as large as the base plate. It should be noted that the flow-through unit and the plate structure are smaller than the base plate, particularly much smaller. There is virtually no restriction to the design of channel cavity courses in the cooperating channel structure and base plate. The base plate could have depressions that cooperate with an exterior side of the channel structure so that closed channel cavities are formed or the channel structure could have depressions that cooperate with an exterior side of the base plate so that closed channel cavities are formed or the base plate as well as the channel structure could have depressions that cooperate to form closed channel cavities. Here, “closed channel cavity” should not exclude that e.g. a filling plug is provided to fill the channel cavities with a fluid sample from the exterior of the microfluidic device, e.g. using a syringe.

In a further embodiment of the invention, the microfluidic device has at least a wall element for preventing a lateral flow from the first flow-through site to the second flow-through site. In this way, the fluid is forced to flow through the flow-through sites and selective properties of the flow-through unit can e.g. be used to prevent flow-through of certain components of the fluid. The wall element could be part of the channel structure or of the base plate, or base plate and channel structure could each have a cooperating wall element.

In one embodiment of the invention, the flow-through unit and the base plate are arranged adjoining each other. This allows independent manufacture of base plate and flow-through unit and easy assembly (e.g. by gluing) without the need for precise measures of a recess into which the flow-through unit is to be arranged and of the flow-through unit itself. To allow fluid flow through the flow-through sites of the flow-through unit, the base plate has two through-going recesses that are positioned so that their relative positions agree with the relative positions of the flow-through sites of the flow-through unit. Then the flow-through unit can be arranged adjoining the base plate so that the flow-through sites coincide with the through-going recesses of the base plate.

In yet another embodiment of the invention, an active element is provided in the plate structure. Such an active element could be a sensor for measuring a property of the fluid (e.g. the temperature) or for selectively measuring the presence and/or the frequency of a certain component or components of the fluid (e.g. a certain protein). Another example of an active element would be an actuator for acting on the fluid and thereby driving the flow.

In a further embodiment of the invention, the flow-through unit has at least one electric via (a conducting through-connection) for providing an electric connection from one side of the flow-through unit to the other. In this way, an electric connection between a data processing device a power supply with an active element provided in the plate structure can be readily established.

The invention also relates to a method of using a microfluidic device according to claim 1, the method including the steps of

guiding the flow through a first channel cavity in a lateral direction or providing a fluid sample in a first volume;

guiding the flow from the first channel cavity or from the first volume into a second channel cavity through a first flow-through site in a vertical direction;

guiding the flow through the second channel cavity in a lateral direction; and

guiding the flow from the second channel cavity into a third channel cavity or a second volume through a second flow-through site in a vertical direction.

The fluid flow as described above could also be reversed and the fluid sample could be reused.

In another embodiment, the method of using the microfluidic device also includes the step of measuring a property of the fluid sample or the presence and/or the frequency of a component of the fluid sample.

The invention further relates to a method of guiding the flow of a fluid sample through a microfluidic device comprising the steps of:

guiding the flow through a first channel cavity in a lateral direction or providing a fluid sample in a first volume;

guiding the flow from the first channel cavity or from the first volume into a second channel cavity through a first flow-through site in a vertical direction;

guiding the flow through the second channel cavity in a lateral direction; and

guiding the flow from the second channel cavity into a third channel cavity or a second volume through a second flow-through site in a vertical direction.

The invention furthermore relates to a method of manufacturing a microfluidic device comprising the steps of:

providing a base plate that extends in a lateral plane and that has at least one through-going recess in a vertical direction;

arranging a flow-through unit having at least a first and a second flow-through site relatively to the base plate, particularly arranging the base plate and the flow-through unit so as to adjoin each other;

arranging a plate structure and the flow-through unit relatively to each other so that a linking channel cavity is formed that enables a lateral fluid flow from the first to the second flow-through site.

Here, the step of arranging the plate structure and the flow-through unit relatively to each other can be carried out before the flow-through unit is arranged relatively to the base plate.

These and other aspects of the invention will be apparent from and elucidated with reference to the embodiments described hereinafter.

### IN THE FIGURES

FIG. 1 shows a perspective view of a part of a microfluidic device according to the invention,

FIG. 2 shows a cross-sectional view of the part of the microfluidic device shown in FIG. 1, the cross section being taken along the line A-A′ of FIG. 1,

FIG. 3 shows a cross-sectional view of a second embodiment of a microfluidic device according to the invention,

FIG. 4 shows a third embodiment of a microfluidic device according to the invention,

FIG. 5a shows a cross sectional view through the microfluidic device in a first stage of its manufacture,

FIG. 5b shows a top view of the microfluidic device in a first stage of its manufacture,

FIG. 6a shows a cross sectional view through the microfluidic device in a second stage of its manufacture,

FIG. 6b shows a top view of the microfluidic device in a second stage of its manufacture,

FIG. 7a shows a cross sectional view through the microfluidic device in a third stage of its manufacture,

FIG. 7b shows a top view of the microfluidic device in a third stage of its manufacture,

FIG. 8a shows a cross sectional view through the microfluidic device in a fourth stage of its manufacture,

FIG. 8b shows a top view of the microfluidic device in a fourth stage of its manufacture,

FIG. 9 shows an embodiment of a microfluidic device where the linking channel cavity is formed by a part of the recess of the base plate and exterior sides of the flow-through unit and the plate structure,

FIG. 10 shows an embodiment of a microfluidic device where one of the flow-through sites is formed by a through-going hole in the flow-through unit,

FIG. 11 shows an embodiment of a microfluidic device where the linking channel cavity is formed by a depression in the flow-through unit cooperating with an exterior side of the plate structure, and

FIG. 12 shows an embodiment of a microfluidic device where the channel cavities are formed by cooperating depressions.

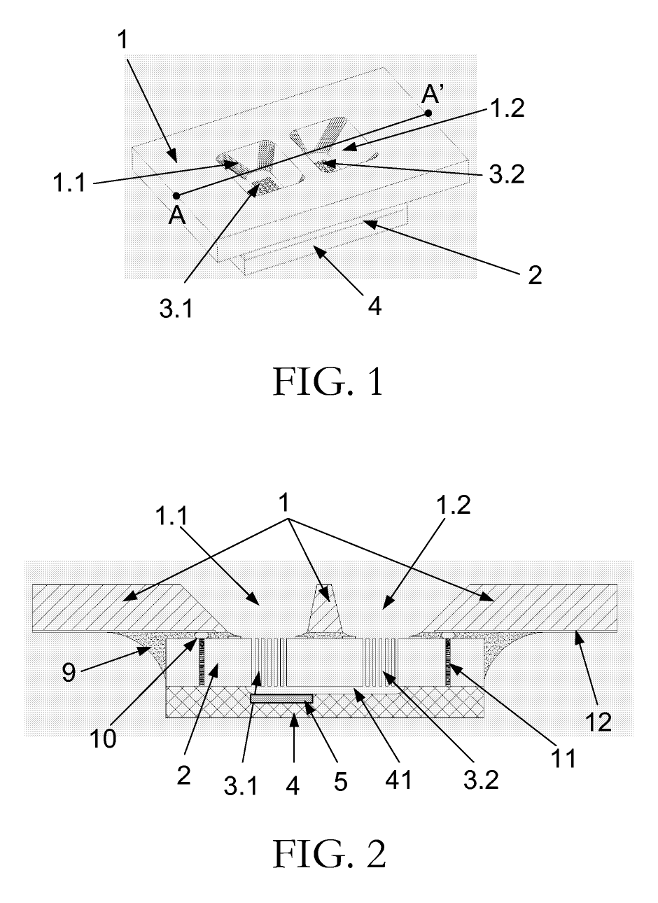

FIG. 1 is a perspective view of a part of an embodiment of a microfluidic device according to the invention. The shown part consists of a base plate 1, a flow-through unit 2 and a plate structure 4. The positional relation between these three components is shown in more detail in FIG. 2. The base plate 1 could be larger than shown here and the depicted size of the base plate in relation to the other components is not restrictive. In this embodiment, the base plate has two through-going recesses 1.1 and 1.2 which are provided in such a way that they coincide with the relative positions of the flow-through sites 3.1 and 3.2 of the flow-through unit. The recesses 1.1 and 1.2 allow a fluid flow from the volume above the base plate 1 through the flow-through sites 3.1 and 3.2 of the flow-through unit 2 and vice versa. In this embodiment the flow-through sites 3.1 and 3.2 comprise micro-channels, some of which can be seen at the bottom of the recesses 1.1 and 1.2. A base plate 1 as shown could be manufactured using a plastic injection molding technique. One metal tool used in the plastic injection molding process can then serve to manufacture thousands of base plates for microfluidic devices. The base plate 1 can also be made of a more or less flexible material, e.g. a plastic foil. Such foils can be made with foil processing techniques for mass manufacturing, well known to persons skilled in the art. In the case of thin foils (e.g. 10 um), the through-going recesses could be made by lithography or laser drilling.

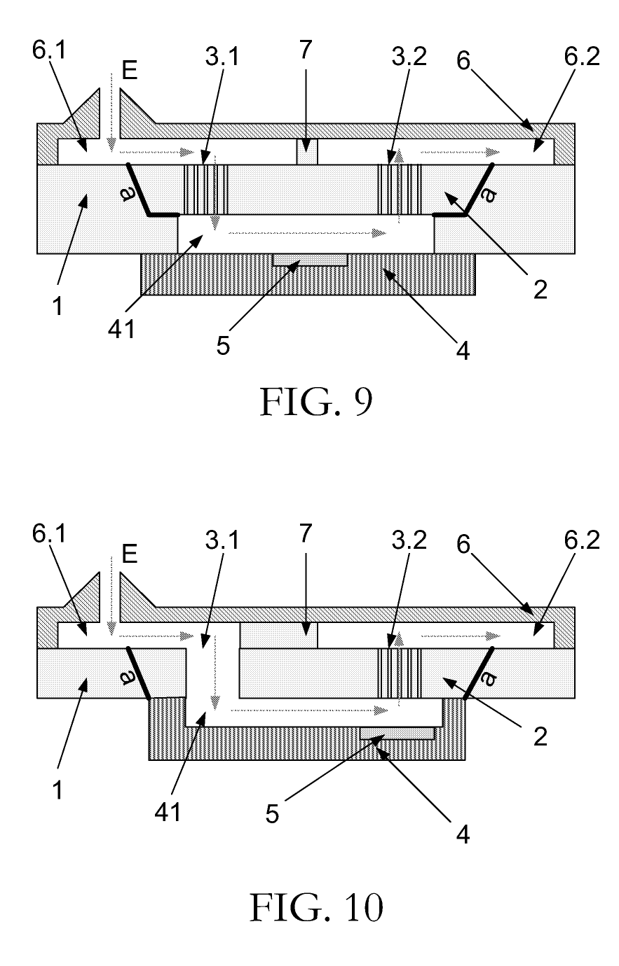

FIG. 2 is a cross sectional view, taken along the line A-A′, of the part of the microfluidic device shown in FIG. 1 . In this cross section, the base plate 1 is cut into three parts. The centre part is the bridge structure between the recesses 1.1 and 1.2 (see also FIG. 1 for reference). In this embodiment the flow-through unit 2 is glued to the base plate using an adhesive material 9, preferably a biocompatible adhesive material, e.g. a resin. As a result, the flow-through unit 2 is arranged integrally with the base plate 1 so that the flow-through sites 3.1 and 3.2 are positioned at the recesses 1.1 and 1.2 of the base plate 1. The recesses 1.1 and 1.2 are tapered towards the flow-through sites 3.1 and 3.2 to support a laminar fluid flow and to minimize areas of recirculation. Other forms of the through-going recesses are also contemplated. In this embodiment, the flow-through unit 2 covers a depression in a plate structure 4 so that a linking channel cavity 41 is formed that connects the first and the second flow-through site 3.1 and 3.2. The linking channel cavity 41 can - as explained further below in conjunction with FIGS. 9 to 11—be formed from depressions worked into the plate structure 4 and/or the flow-through-unit 2 and/or the base plate 1. A vertical fluid flow from a volume above the base plate 1 through the micro-channels into the linking channel cavity 41 (or a reversed flow from the linking channel cavity 41 to the volume above the base plate 1) is thus enabled. In another embodiment a porous membrane is used instead of micro-channels. In a further embodiment, as explained below, one of the flow-through sites is designed as a single hole rather than a partitioned hole, e.g. for minimized obstruction of the flow (see also FIG. 10 for reference). The plate structure 4 could for example be made (etched) from silicon or could be a molded plastic part. In the plate structure 4 an active component 5, e.g. a sensor or an actuator or a pump etc., could be integrated. In the depicted embodiment, the active component 5 is electrically connected. This is accomplished by having leads 12 on the base plate (e.g. copper leads that have been embedded inside or printed onto the base plate). The leads are coupled via conductive bumps 10 to electrical vias 11 in the flow-through unit 2. The plate structure also has electrical leads or wires (not shown) that are electrically coupled to the electrical vias 11, so that a connection to the active component 5 can be established. Energy supply and data exchange can thus be implemented. In another embodiment, the active component 5 communicates via an optical module or an RF module and receives data and/or power via an antenna and/or via a photodiode. Any kind of active element 5, e.g. a sensor, an actuator etc., is useful for a microfluidic device, especially for a microfluidic device that is designed as a biosensor cartridge.

The microchannels or the porous membrane(s) defining the flow-through sites 3.1 and 3.2 could be used for various purposes. In case a gas bolus flowsthrough the channel cavities of the microfluidic device, the vertical flow-through unit 2 avoids that the gas bolus also flows over the active element 5, as the gas bolus does not flow through the flow-through sites. The flow-through sites 3.1 and 3.2 could be used to filter the fluid or for selective fluid flow, e.g. if the fluid is a blood sample, the channel size could be chosen so that blood cells could not flow through and only the blood plasma would flow over the active element 5. The microchannels could also be used to specifically bind target molecules. If receptor molecules are attached to the microchannel walls, these receptor molecules will capture the targets. Due to the high surface to volume ratio, target molecules can be captured in large quantities, which leads to a high signal, e.g. in case the target molecules are labeled with a fluorescent marker or a magnetic bead and the signals from the labels are measured with an optical sensor (e.g. a photodiode) or a magnetic sensor, respectively. The active element 5 could be such an optical or magnetic sensor. In these cases, a strong fluorescent light signal can be measured after excitation of the fluorescent transition, or a strong deviation in magnetic characteristics can be measured. In case magnetic beads are attached to the target molecules, the active element 5 could be a giant magneto-resistive (GMR) sensor for measuring the magnetic characteristics in one or both of the flow-through sites 3.1 and 3.2 as described in European patent application no. 04102257.5.

From the embodiment as shown in FIG. 2 it can be seen that the plate structure 4 has virtually the same lateral extensions as the flow-through unit 2. The plate structure 4 could also have somewhat larger lateral extensions or smaller lateral extensions. This allows the manufacture of a microfluidic device having two channel layers at different vertical positions in a cost-effective way, as is described in more detail further below.

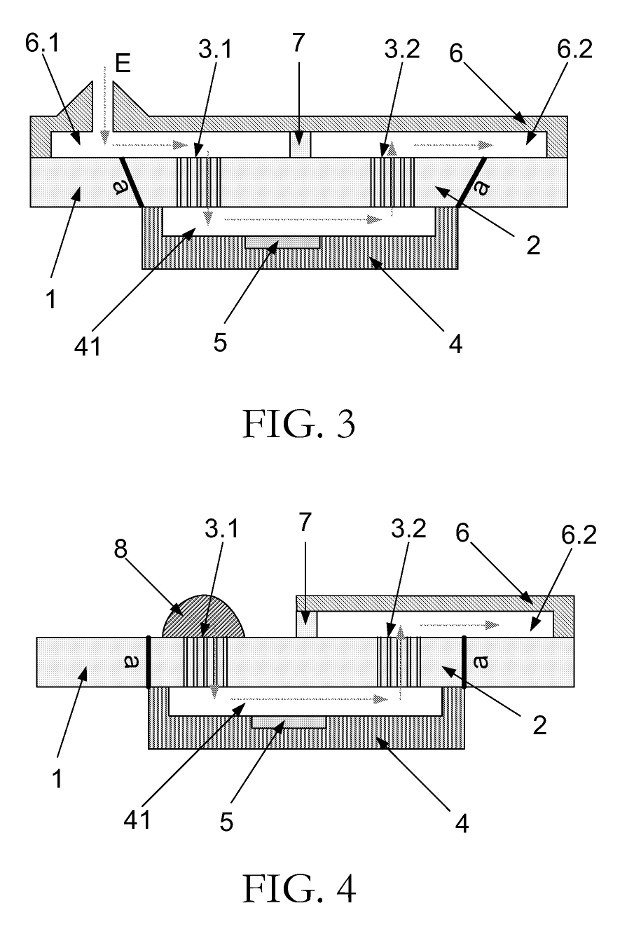

In FIG. 3, a cross sectional view of a first embodiment of a microfluidic device according to the invention is schematically shown. A base plate 1 is arranged integrally with a flow-through unit 2. Here, the integral arrangement is accomplished by gluing the flow-through unit 2 into a recess of the base-plate 1. By bold lines a it is indicated that such a recess could be made in a tapered form so as to enable easy gluing of the flow-through unit 2 into the recess. In another embodiment, the flow-through unit 2 is integrated into the base plate 1 during the plastic injection molding process, in which case the flow-through unit 2 is put into the tool used for manufacturing the plastic injection molded base plate 1. A strong connection between flow-through unit 2 and base plate 1 can be assured by using structured interface sides, so that the plastic matrix interleaves with the structures. The relative positional arrangement of base-plate 1 and flow-through unit 2 could also be effected as shown in FIG. 1 and 2.

A plate structure 4 is arranged adjoining the flow-through unit 2. Referring to the directions in the drawing, the plate structure 4 is arranged underneath the flow-through element so that a linking channel cavity 41 is formed by a depression in plate structure 4 and the adjoining exterior side of the flow-through unit 2, which linking channel cavity 41 connects the first and the second flow-through sites 3.1 and 3.2. A channel structure 6 is arranged atop the base plate 1. The channel structure 6 could likewise be made by a plastic injection molding process, or by other techniques known to a person skilled in the art, e.g. by hot embossing of a plastic master or by milling or wire erosion techniques. The channel structure 6 has a filler plug E, which is provided for filling the microfluidic device by a syringe. The channel structure 6 has depressions that together with the base plate 1, form channel cavities 6.1 and 6.2. In one embodiment, the channel cavity 6.1 is connected with the channel cavity 6.2 so that a lateral fluid flow is enabled over the area of the flow-through unit 2. In another embodiment, a wall element 7, which could be an integral part of the channel structure 6 (e.g. could be a structure of the channel structure 6 made in the plastic injection molding process), sits between the channel cavities 6.1 and 6.2 so that a direct lateral fluid flow from flow-through site 3.1 to flow-through site 3.2 is disabled. The grey dashed arrows indicate a possible fluid flow through the microfluidic device when the wall element 7 is present. After the fluid sample has been filled into channel cavity 6.1, the fluid sample first flows laterally in channel cavity 6.1 to flow-through site 3.1, and then it flows vertically through flow-through site 3.1 into linking channel cavity 41. In linking channel cavity 41 the fluid sample flows laterally to flow-through site 3.2, where it vertically flows into channel cavity 6.2. From there the fluid could flow into a container cavity (not shown) for storage or further processing of the fluid after the sample has passed the channel system. A reversed fluid flow could also be possible, particularly if the fluid sample should be reused or for guiding the fluid sample repeatedly through the microfluidic device.

In FIG. 4, a cross section of a further embodiment of a microfluidic device according to the invention is shown. In this embodiment, a fluid sample is provided in a volume 8 atop the first flow-through site 3.1. This could e.g. be a blood sample or a urine sample. The fluid sample vertically flows through flow-through unit 2 at flow-through site 3.1 into channel cavity 41 of the plate structure 4 by capillary forces or by applying a low pressure, e.g. by using a pump (not shown) that sucks or pushes the fluid sample into the microfluidic device and through the linking channel cavity 41, the flow-through unit 2 and the channel cavity 6.2.

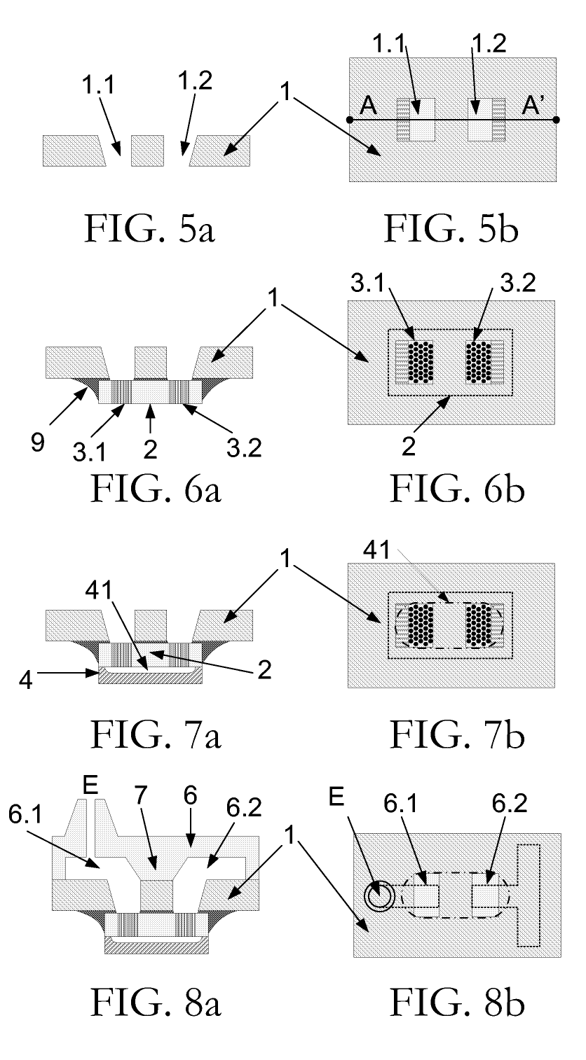

In the following, a method of manufacturing a microfluidic device is described with reference to FIGS. 5a, b-8a, b. In FIGS. 5b-8b there is shown a top view of the microfluidic device in its various manufacturing steps and in FIGS. 5a-8a there is shown a cross sectional view of the microfluidic device in the respective manufacturing step, where the cross sectional views are each taken along a line A-A′ as indicated in FIG. 5b.

In FIGS. 5a, b, as a first step a base plate 1 is provided. Such a base plate 1 can be made by a plastic injection molding process, by a foil manufacturing process, by an embossing technique, a milling process or the like. For the plastic injection process a metal tool is made that is a negative of the final base plate. By etching and/or milling and/or wire erosion such tools can be precisely manufactured. Due to the low abrasive effect of plastic, the negative can be used for thousands of plastic injection molded base plates. In this embodiment, the base plate 1 has two recesses 1.1 and 1.2 and no further depressions. The two recesses are tapered. In FIG. 5b, the tapered walls are indicated by horizontally striped areas. In case that the base plate 1 is a very thin foil (e.g. 10 um), it could be provided on a sacrificial support structure (not shown) for adding stability. In this case, the manufacturing step as described with reference to FIGS. 8a and 8b, namely arranging the channel structure 6 atop the base plate 1, would be performed first and then the sacrificial support structure would be removed, e.g. by peeling it away or by chemically dissolving it.

In a next step, as shown in FIGS. 6a, b, a flow-through unit 2 is glued to the base plate by using an adhesive material 9. The flow-through unit 2 has a first and a second flow-through site 3.1 and 3.2. The first and the second flow-through sites 3.1 and 3.2 are spatially separated. The flow-through unit 2 is glued to the base plate 1 in such a way that a positional coincidence between the first and second flow-through sites 3.1 and 3.2 and the recesses 1.1 and 1.2 results. The outer lateral dimensions (length and width) of the flow-through unit 2 are indicated by a dotted line in FIG. 6b, as the flow-through unit 2 is glued underneath the base plate 1 in this top-view drawing. In the shown embodiment, the flow-through sites 3.1 and 3.2 are formed by microchannels, as indicated in the cross-sectional view (FIG. 6a) by vertical lines and by black circular holes in the top view (FIG. 6b). In another embodiment the microchannels are not purely vertically oriented but inclined.

In the third step, as shown in FIGS. 7a, b, a plate structure 4 is glued to the flow-through unit 2 opposite to the base plate 1 such that a linking channel cavity 41 is formed. In this embodiment, the linking channel cavity 41 is formed by a depression in the plate structure 4 and by an adjoining side of the flow-through unit 2 that covers the depression in the plate structure 4. The resulting closed linking channel cavity 41 connects the first and the second flow-through sites 3.1 and 3.2 so that a lateral flow between them is enabled. The lateral dimensions (length and width) of the linking channel cavity 41 are indicated in FIG. 7b by a dashed-dotted line.

In another alternative to the described manufacturing method, the flow-through unit 2 is attached to the plate structure 4. In case that the plate structure 4 is made from silicon, this attachment can be realized at wafer level, e.g. using a known wafer-to-wafer bonding procedure. The sandwiched wafer structure is then diced, preferably with the flow-through unit 2 facing down on a carrier, so that contamination of the flow-through unit 2 is avoided. In such a process, a plurality of bonded sandwich structures of flow-through unit 2 and plate structure 4 can be manufactured. Each sandwich structure is then glued to a base plate 1, as shown in FIGS. 5a, b for the flow-through unit 2 alone, and the result as shown in FIGS. 7a, b is achieved.

In a last step, a channel structure 6 is glued to the base plate 1, as shown in FIGS. 8a, b. The channel structure 6 could also be made by a plastic injection molding process. The top side (referring to the directions in the drawing) of the base plate 1 and the bottom side of the channel structure 6 are glued together and channel cavities 6.1 and 6.2 for guiding the flow of a fluid sample are formed. For this purpose, the channel structure has depressions that form the channel cavities 6.1 and 6.2 when glued to the adjoining side of the base plate 1. A wall element 7 between the formed channel cavities 6.1 and 6.2 coincides with the bridge structure between the recesses 1.1 and 1.2. In this way a lateral flow from channel cavity 6.1 to channel cavity 6.2 is inhibited and the fluid sample that may be injected via filler plug E is forced to vertically flow through the flow-through unit 2 at the first flow-through site 3.1 into the linking channel cavity 41. The outer (lateral) dimensions of the channel cavities 6.1 and 6.2 are shown as dotted lines in the top view of FIG. 8b. The channel cavity 6.2 is formed in a T-shape so that a storage cavity is formed. Tapered walls, micro-channel holes and the dimensions of the flow-trough unit 2 are neglected in FIG. 8b for the sake of simplicity.

FIGS. 5a, b-8a, b are schematic drawings, and dimensions of the various elements of the shown microfluidic device are not to be construed in a restrictive sense. Typical values, also not be construed in a limiting sense, for the various dimensions are given in the table below. In the table “um” means micrometer. Width and length are the lateral dimensions and height is the vertical dimension.

| Component | |
|---|---|
| of the | |
| microfluidic | Typical size |
| device | (width × length × height) |
| Base plate 1 | 2 mm × 2 mm × 10 um . . . 10 cm × 10 cm × 2 mm |
| Flow through | 200 um × 200 um × 10 um . . . 2 cm × 2 cm × 500 um |
| unit 2 | |
| Flow through | 10 um × 10 um × 10 um . . . 2 mm × 2 mm × 500 um |
| sites 3.1, 3.2 | |
| Channel | 2 mm × 2 mm × 30 um . . . 20 cm × 20 cm × 2 cm |
| structure 6 | |
| Channel | 2 mm × 2 mm × 10 um . . . 20 cm × 20 cm × 1 mm |
| cavities | |
| 6.1, 6.2 | |
| Plate | same range as plate 1 |
| structure 4 | |
| Channel | same range as cavity 6.1 |
| cavity 4.1 | |

Further embodiments of the microfluidic device according to the invention are discussed in conjunction with FIGS. 9-12.

In FIG. 9, an embodiment of a microfluidic device is shown where the flow-through unit 2 is glued into a tapered recess of the base plate 1 so that a flat surface results on which the channel structure 6 is arranged. The dimensions of the flow-through unit are indicated by lines a. In this embodiment, the base plate is thicker than the flow-through unit so that a part of the recess remains. A plain plate structure 4 is arranged to cover this depression, so that a linking channel cavity 41 is formed. In this embodiment, the linking channel cavity 41 is formed by an exterior side of the flow-through unit 2, the remaining part of the recess of the base plate 1 and an exterior side of the plate structure 4. In another embodiment, also the plate structure 4 has a depression that works together with the recess in the base plate 1 so that the linking channel cavity 41 is formed as result of the depression and the recess.

In FIG. 10, an embodiment of a microfluidic device is shown, where the first flow-through site 3.1 is designed as a hole in the flow-through unit 2. Alternatively, the first flow-through site 3.1 can also be designed as a number of holes or channels having a size larger than all components in the fluid sample, so that selective filtering is not enabled. The second flow-through site 3.2 is designed for selective filtering of fluid sample components, particularly cells, which cannot pass through the small-sized microchannels. If the cells have an optical or magnetic label, their presence or other properties can be measured by an active element 5 that is constructed as a sensor and positioned directly underneath the second flow-through site 3.2. For this effect, the microchannels of the second flow-through site 3.2 are designed smaller than the cells, so that the cells cannot flow through the second flow-through site. The cells therefore remain trapped by mechanical means in the volume of the linking channel cavity 41 between the second flow-through site 3.2 and the active element 5.

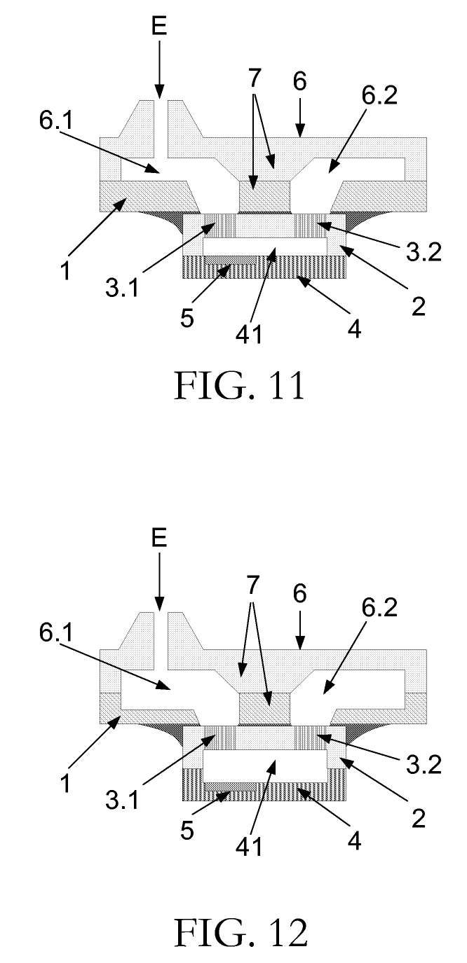

In FIG. 11, an embodiment of a microfluidic device is shown, where the flow-through unit 2 is glued to the base plate 1. The flow-through unit 2 has a depression on the side opposite to the side that is glued to the base plate 1. In this embodiment, the plate structure 4 is arranged to cover the depression in the flow-through through unit 2 to form the linking channel cavity 41. This embodiment is similar to the embodiment of a microfluidic device as shown in FIG. 8a, where the depression was solely formed in the plate structure 4.

In FIG. 12, a further embodiment of a microfluidic device is shown. In this embodiment, the base plate 1 has depressions that cooperate with depressions in the channel structure 6 so that closed channel cavities 6.1 and 6.2 are formed. Wall elements 7 that are each an integral part of the channel structure 6 and of the base plate 1, respectively, cooperate to inhibit a lateral fluid flow between the first and the second flow-through sites 3.1 and 3.2 in the lateral channel layer defined by channel cavities 6.1 and 6.2. Additionally, depressions are formed in the flow-through unit 2 as well as in the plate structure 4, so that the linking channel cavity 41 is formed by these two cooperating depressions.

1. Microfluidic device for guiding the flow of a fluid sample comprising
a base plate (1) extending in two lateral directions and having at least one through-going recess (1.1) in the vertical direction;
a flow-through unit (2) having at least a first and a second flow-through site (3.1, 3.2); and
a plate structure (4), wherein
the flow-through unit (2) is arranged relatively to the recess (1.1) of the base plate (1) so that a vertical fluid flow from one side of this arrangement to the opposite side through each of the first and the second flow-through sites (3.1, 3.2) is enabled; and
the plate structure (4) and the flow-through unit (2) are arranged relatively to each other so that a linking channel cavity (41) is formed for enabling a lateral fluid flow from the first to the second flow-through site (3.1, 3.2).

2. Microfluidic device according to claim 1, wherein the plate structure (4) has essentially the same or smaller lateral extensions than the flow-through unit (2).

3. Microfluidic device according to claim 1, wherein the linking channel cavity (41) is formed by a depression in the flow-through unit (2) cooperating with an exterior side of the plate structure (4) or by a depression in the plate structure (4) cooperating with an exterior side of the plate structure (4) or by two cooperating depressions in the flow-through unit (2) and the plate structure (4), or the linking channel cavity (41) is formed by a part of the recess (1.1) of the base plate (1) and cooperating exterior sides of the flow-through unit (2) and the plate structure (4), where at least one of the exterior sides could alternatively be a cooperating depression in one of the flow-through unit (2) or the plate structure (4).

4. Microfluidic device according to claim 1, wherein a channel structure (6) is arranged on the arrangement of base plate (1) and flow-through unit (2) so that at least a channel cavity (6.1) is formed by at least a depression in the base plate (1) cooperating with an exterior wall of the channel structure (6) or by a depression in the channel structure (6) cooperating with an exterior side of the base plate (1) or by two cooperating depressions in the base plate (1) and the channel structure (6).

5. Microfluidic device according to claim 4, wherein the microfluidic device has at least a wall element (7) for preventing a lateral fluid flow between the first and the second flow-through site (3.1, 3.2) in the channel structure (6).

6. Microfluidic device according to claim 1, wherein the flow-through unit (2) and the base plate (1) are arranged so as to vertically adjoin each other and the base plate has at least two through-going recesses (1.1, 1.2) in the vertical direction at the position of the flow-through sites (3.1, 3.2).

7. Microfluidic device according to claim 1, wherein an active element (5) is provided in the plate structure (4).

8. Microfluidic device according to claim 1, wherein the flow-through unit (2) has at least one electric via (11) for providing an electric connection from one side of the flow-through unit (2) to another.

9. Method of using a microfluidic device according claim 1, comprising the steps of
providing a fluid sample in a volume (8) adjacent the first flow-through site (3.1), guiding the fluid sample through the first flow-through site (3.1) into the linking channel cavity (41),
guiding the fluid sample through the linking channel cavity (41) from the first flow-through site (3.1) to the second flow-through site (3.2),
guiding the fluid sample through the second flow-through site (3.2) into a channel cavity (6.2).

10. Method according to claim 9 wherein the steps further include a step of measuring a property of the fluid sample or the presence and/or the frequency of a component of the fluid sample.

11. Method for guiding the flow of a fluid sample through a microfluidic device comprising the steps of:
guiding the flow through a first channel cavity (6.1) in a lateral fashion or providing a fluid sample in a first volume (8);
guiding the flow from the first channel cavity (6.1) or from the first volume (8) into a second channel cavity (41) through a first flow-through site (3.1) in a vertical fashion;
guiding the flow through the second channel cavity (41) in a lateral fashion; and
guiding the flow from the second channel cavity (41) into a third channel cavity (6.2) or a second volume through a second flow-through site (3.2) in a vertical fashion.

12. Method for manufacturing a microfluidic device comprising the steps of:
providing a base plate (1) that extends in a lateral plane and that has at least one through-going recess (1.1) in a vertical direction;
arranging a flow-through unit (2) having at least a first and a second flow-through site (3.1, 3.2) relatively to the base plate (1), particularly arranging the base plate (1) and the flow-through unit (2) adjoining each other;
arranging a plate structure (4) and the flow-through unit (2) relatively to each other so that a linking channel cavity (41) is formed that enables a lateral fluid flow from the first to the second flow-through site (3.1, 3.2).
